(19) United States
(12) Patent Application Publication
(10) Pub. No.: US 2025/0004086 A1
(43) Pub. Date: Jan. 2, 2025

(54) COMPUTER-IMPLEMENTED METHOD FOR PROVIDING A CONTROL SEQUENCE TO BE USED, METHOD FOR RECORDING MEASUREMENT DATA, MAGNETIC RESONANCE FACILITY, COMPUTER PROGRAM AND ELECTRONICALLY READABLE DATA CARRIER

(71) Applicant: Siemens Healthineers AG, Forchheim (DE)

(72) Inventors: Jürgen Herrler, Erlangen (DE); Patrick Liebig, Erlangen (DE)

(21) Appl. No.: 18/756,141

(22) Filed: Jun. 27, 2024

(30) Foreign Application Priority Data
Jun. 28, 2023 (DE) 10 2023 206 073.6

(51) Int. Cl. G01R 33/561; G01R 33/24; G01R 33/28; G01R 33/54

(52) U.S. Cl. CPC G01R 33/5612; G01R 33/246; G01R 33/288; G01R 33/543

(57) ABSTRACT

A computer-implemented method for providing a control sequence to be used for establishing a target excitation state for a detection process of measurement data of an examination object with a magnetic resonance facility. The control sequence includes high frequency pulses to be output via transmission channels of a high frequency coil arrangement. The method includes providing field distribution maps recorded on the examination object, including a B0 map and at least one B1 map, providing a precalculated control sequence with a total output duration, dividing the total output duration into a plurality of time periods with a time period duration, assigning a complex optimization factor to each time period and transmission channel by which the pulse shape of the high frequency pulse for the transmission channel is to be multiplied in accordance with the precalculated control sequence within the time period, optimizing the complex optimization factors in an optimization process to optimally achieve the target excitation state taking into account the field distribution maps, and determining the control sequence to be used by time period multiplication of the pulse shapes by the respective optimized optimization factors.

### CROSS REFERENCE TO RELATED APPLICATIONS

This application claims the benefit of DE 10 2023 206 073.6 filed on Jun. 28, 2023, which is hereby incorporated by reference in its entirety.

### FIELD

Embodiments relate to a computer-implemented method for providing a control sequence to be used for establishing a target excitation state for a detection process of measurement data of an examination object with a magnetic resonance facility.

### BACKGROUND

In magnetic resonance imaging, for example for medical applications, it has been proposed to also use higher magnetic field strengths of the basic magnetic field (B0 field) as a higher image quality of the measurement data may then be achieved. Magnetic field strengths of 7 Tesla or more are referred to as so-called ultrahigh field magnetic resonance imaging (UHF-MRI). However, the high basic magnetic field also results in a short Larmor wavelength, that may lead to the high frequency excitation field (B1 field) becoming spatially highly inhomogeneous. The reason for this may be found, for example, in the relatively good tissue conductivity for high frequencies and reflections at interfaces between different biological tissues or biological tissue and air. In addition, even small deviations in the homogeneity of the basic magnetic field lead to significantly different Larmor frequencies.

This may lead to a desired target excitation state, for example, a certain, homogeneous flip angle of the spins of the examination object, not being achieved.

In this regard, it has been proposed to use high frequency coil arrangements with a plurality of transmission channels and to use the transmission technology of parallel transmit (pTx). In this case, a plurality of high frequency coils (transmission coils) are controlled via respective transmission channels, each with its own high frequency pulses of different pulse shapes, the high frequency excitation field (B1 field) resulting as interference of the fields generated by the individual high frequency coils. It may therefore be controlled in its spatial distribution.

In this case, a distinction may be drawn between the so-called static pTx and the so-called dynamic pTx. In the case of static parallel transmission, all transmission channels are subjected to the same high frequency pulse shape, for example, a rectangular shape or a sinc shape, that are scaled with transmission channel-specific magnitudes and phases. This generates a (static) excitation field that is spatially more homogeneous than an uncalibrated excitation field. In dynamic parallel transmission, time-varying B1 fields are generated, each of which is inhomogeneous in itself, that are applied simultaneously with equally time-varying B0 gradient fields that describe a transmit k-space trajectory. In this way, highly homogeneous flip angle distributions may be achieved at the end of dynamic parallel transmission.

Finally, in parallel transmission, it is also known to provide a plurality of high frequency pulses that, for example, follow one another in time, per transmission channel in order to homogenize the spatial distribution of the flip angle across a plurality of high frequency pulses. This approach is also referred to as multi-pulse pTx.

In order to achieve desired target excitation states, optimization methods are usually used to determine the optimization parameters that describe the pulse shapes and the time sequence of the dynamic and/or multi-pulse pTx control sequences. However, the optimization of dynamic control sequences and multi-pulse control sequences for parallel transmission is extremely complex, computationally expensive and dependent on the anatomical nature and position or orientation of the recording area on the examination object, for example, a part of the body of a patient. Individual high frequency pulses that are optimal for a specific measurement process and, if necessary, gradient pulses may therefore only be calculated once field distribution maps of the examination object have been recorded, and consequently the examination object is already prepared for examination. With lengthy optimization processes for the pTx pulses, this leads to very long and clinically unmanageable delays in the examination.

Therefore, various approaches have already been proposed in order to enable more rapid readiness for measurement processes on objects to be examined in magnetic resonance facilities.

The concept of universal pulses has shown that a large part of the inhomogeneities may be compensated by pre-calibrated pTx pulses, that are therefore optimized before the actual examination, if the universal pulses are determined with field distribution maps of a plurality of subjects. In other words, in the concept of universal pulses, the optimization takes place for a cohort of reference objects to be examined and once optimized, the pulses are then used for all objects to be examined without further calibration. This approach is described in more detail, for example, by WO 2017/060142 A1 or the article by Vincent Gras et al., “Universal Pulses: A New Concept for Calibration-Free Parallel Transmission”, Magnetic Resonance in Medicine 77 (2017), pages 635 to 643.

In order to further improve this approach, procedures have been proposed that allow a quickly implementable, further improvement of precalculated control sequences, for example with universal pulses, immediately prior to an examination. In an article by Caroline Le Ster et al., “Standardized universal pulse: A fast RF calibration approach to improve flip angle accuracy in parallel transmission”, Magnetic Resonance in Medicine 87 (2022), pages 2839-2850, the concept of standardized universal pulses (SUP) is explained. It proposes the use of a so-called standardized database in which each B1+map has been normalized to a reference transmit high frequency field distribution. When recording a new examination object, a rapid detection of three B1+layers is carried out in order to adapt the standardized universal pulses by a linear transformation.

Another possibility is known by the name FOCUS and is described, for example, in an article by Jürgen Herrler et al., “Fast online-customized (FOCUS) parallel transmission pulses: A combination of universal pulses and individual optimization”, Magnetic Resonance in Medicine 85 (2021), pages 3140-3153. In addition, reference is made to EP 3 809 151 A1. Here, universally optimized transmit k-space trajectories, that may be described by a small number of parameters, high frequency pulse shapes and associated parameters relevant for optimization, for example for energy regularization and/or as sub-pulse durations, are used in order to then, after recording field distribution maps, further individually optimize the pulses, for example the pulse shapes.

In a development of this approach, EP 3 901 648 A1 proposes a method and an apparatus for controlling a magnetic resonance imaging system. Pulse data is selected or calculated in a pulse design unit for generating pulse data for controlling the magnetic resonance imaging system. Based on a set of B0 and B1 maps of different patients, pulses are configured by interpolation on a grid and/or based on a neural network. A lexicon of selective pulses may be formed on the grid so that optimal pulses for a measurement may be determined on the basis of an examination scheme. The examination scheme includes, for example, information about contrasts to be measured and the order and shape of sub-regions of a region of interest to be recorded.

It has also already been proposed to assign precalculated universal pulses to different clusters. Based on the variables describing the current measurement process, a pulse sequence that is particularly suitable for the measurement process may be selected from such cluster-specific pulse sequences. Such variables may be variables related to the examination object. However, it has also been proposed, for example in the context of the above-mentioned FOCUS method, to use field distribution maps, for example B1 maps, as a basis for selecting a cluster-specific pulse sequence. For example, the B1 maps for the current measurement process may be evaluated by a trained cluster determination function, for example including a neural network, to determine a cluster-specific pulse sequence.

In an article by Raphael Tomi-Tricot et al., “SmartPulse, a machine learning approach for calibration-free dynamic RF shimming: Preliminary study in a clinical environment”, Magnetic Resonance in Medicine 82 (2019), pages 2016 to 2031, a calibration-free pulse design method is proposed in this regard, in which a database of field distribution maps based on mutual affinity of their assigned “kT points” pulses was divided into clusters. A machine learning classifier was trained to select the best common “KT points” pulse of the three available clusters based on further field distribution maps.

### BRIEF SUMMARY AND DESCRIPTION

The scope of the present disclosure is defined solely by the claims and is not affected to any degree by the statements within this summary. The present embodiments may obviate one or more of the drawbacks or limitations in the related art. Independent of the grammatical term usage, individuals with male, female or other gender identities are included within the term.

Embodiments specify a possibility for determining improved customized pulses in a clinically acceptable time.

In a computer-implemented method the following steps are provided: provision of field distribution maps recorded on the examination object, including a B0 map and at least one B1 map, provision of a precalculated control sequence with a total output duration, division of the total output duration into a plurality of time periods with a time period duration, assignment of a complex optimization factor to each time period and transmission channel by which the pulse shape of the high frequency pulse for the transmission channel is to be multiplied in accordance with the precalculated control sequence within the time period, optimization of the complex optimization factors in an optimization process to optimally achieve the target excitation state, taking into account the field distribution maps, and determination of the control sequence to be used by time period multiplication of the pulse shapes by the respective optimized optimization factors.

The method makes it possible to provide individually adapted pulses in a control sequence for a specific measurement process on an examination object, for which field distribution maps, i.e. a B0 map and B1 maps for each transmission channel, are measured in a known manner, so that the target excitation state may be achieved as accurately as possible, for example if further boundary conditions are met. For example, it is used in ultrahigh field magnetic resonance imaging, i.e., at basic magnetic field strengths of at least 7 Tesla. It is based on precalculated control sequences that have already been determined prior to the examination, for example for universal use, for example in a comprehensive optimization process that also affects the pulse shapes. For example, the pulses of the precalculated control sequences may be determined as universal pulses and/or cluster-specific pulses, including complex pulse shapes at least for the high frequency pulses, from field distribution maps and/or other information from a cohort of examination objects. Embodiments relate to parallel transmission (pTx), i.e., for example that a plurality of transmission channels with respective high frequency pulses are provided for the realization of a parallel transmission process.

The control sequence may also include at least one gradient pulse for at least one gradient channel of a gradient coil arrangement of the magnetic resonance facility, a real-valued optimization factor being assigned to each gradient channel for each time period, optimized in the optimization process and the pulse shape of the gradient pulse in each time period multiplied by the respective optimized optimization factor in order to determine the control sequence to be used. This means that the precalculated control sequence may already refer to gradient pulses and high frequency pulses with corresponding pulse shapes. The method described here therefore relates to dynamic and/or multi-pulse pTx. Transmit k-space trajectories are used and, for example, also included in the advance calculation, for example in the optimization process, for the precalculated control sequences.

The advance calculations for the determination of the precalculated control sequences are usually extremely complex and result in extremely complicated pulse shapes that are not easy to describe mathematically, for which a large multiplicity of variables to be optimized were used. For example, the pulses of the precalculated control sequences (and also of the resulting control sequences to be used) may not be coherent in time and/or space.

Embodiments divide the total output duration for the precalculated control sequence into a plurality of time periods, each time period and each transmission channel, for example also each gradient channel (i.e., each pulse shape for a gradient coil of the gradient coil arrangement) being assigned an optimization factor that is complex for the high frequency pulses, but real-valued for the gradient pulses. To obtain test control sequences or ultimately the control sequence to be used, the pulse shape of the precalculated control sequence provided for this purpose must be multiplied by the optimization factor for each time period and each transmission channel and, if applicable, gradient channel. In other words, time-period scaling with a complex optimization factor is proposed for the high frequency pulses.

The subsequent optimization process, in order to achieve an individual adjustment based on the field distribution maps for the measurement process, only uses the optimization factors as optimization parameters. In other words, only one complex optimization factor needs to be optimized for each time period and transmission channel (as well as, if necessary, a real-valued optimization factor for each gradient channel) in the optimization process. The pre-optimized pulse shapes of the precalculated control sequence for each individual time period are then scaled with these optimization factors, as a result of which the pulses adapt individually to the B1 and B0 field distribution of the current examination object.

In this way, even very complicated pulse shapes in precalculated control sequences may be optimized quickly and thus in an acceptable time for use in clinical routine, for example in medical imaging. Significantly fewer optimization parameters are required for the optimization process than would be the case if a complete further optimization of the precalculated control sequence took place, i.e., for example if the pulse shapes and the time sequence were the complete subject of the optimization process. Individual optimization using all these optimization parameters relating to the pulse shape and the time sequence would, as has been shown, lead to very long optimization times and to a more unstable optimization process, for example due to conceivable local minima. Suh a complete optimization approach would therefore not be applicable in a clinical environment.

However, investigations have shown that with the proposed division into time periods and scaling, 90% or more of the variability may be covered in many applications and thus increases in the quality of the control sequence to be used may also be achieved in comparison with known individualization approaches of the prior art. Due to the small number of optimization parameters to be optimized, specifically the optimization factors, extremely fast optimization may be achieved in the optimization process, so that it may take just 2 to 10 seconds, for example, 5 seconds.

This offers advantages not only in comparison with universal pulses, that may also be optimized in a very complex manner but are not adapted to the individual field distributions, but also with regard to advanced approaches. Standardized universal pulses only use a linear transformation and thus have limited potential for individual adaptation, whereas the present invention covers a significantly larger proportion of the variability and thus provides high-quality optimization results. FOCUS pulses usually also optimize pulse shapes and therefore have a more complex optimization process. A reduction of the optimization parameters there result in less variability coverage in many cases. In the SmartPulse method, only precalculated universal pulses, for example cluster-specific universal pulses, are selected, but not a complete calculation of individual pulses. In summary, the method proposed here may therefore be used to calculate significantly better, for example more complicated and more individualized, pulses, and therefore control sequences to be used, despite short adaptation times.

The optimal achievement of the target excitation state in the optimization process, as is generally known in the prior art, may be achieved in various ways, for example with regard to division into target functions and boundary conditions. For example, approaches are conceivable in which the achievement of a certain homogeneity or accuracy of the flip angle distribution in the target excitation state is ensured via boundary conditions, while the target function refers to energy inputs, for example SAR minimization. However, the target function may relate to achieving the target excitation state as accurately as possible, while compliance with SAR specifications may be covered by boundary conditions. Hybrid approaches, in which the target function takes into account both energy inputs and deviations from the target excitation state are, of course, also conceivable. Compliance with technical requirements, for example maximum possible power or currents in high frequency and gradient amplifiers or the coil arrangements, is usually mapped via further boundary conditions, but may also be mapped via terms of the target function.

If the steps of the method are carried out by a control facility of the magnetic resonance facility, the precalculated control sequences may, for example, already be provided before the imaging on the examination object takes place, for example already during production or as part of a normal update of the magnetic resonance facility. The required field distribution maps may be recorded with the magnetic resonance facility itself, for example with a recording time of some tens of seconds, for example 30 to 60 seconds. The field distribution maps allow the properties of the examination object to be taken into account. B1 maps each describe the spatial B1 field distribution for a specific transmission coil of the transmission coil arrangement, i.e., for a specific transmission channel of the high frequency coil arrangement. In other words, the B1 maps describe the spatial sensitivity of the corresponding transmission coil. B0 maps describe, spatially resolved, the deviations of the basic magnetic field (B0 field) from the actually desired homogeneous field profile, and thus the local deviation of the Larmor frequency from the desired (nominal) Larmor frequency.

The respective time period durations of the plurality of time periods may be the same or different. For example, all time period durations may differ from one another or only a part thereof. In a preferred embodiment of the invention, it may be provided that the time period duration is selected to be the same for all time periods. In this way, it is possible to divide up the total output duration over time in a way that is easy to implement, while still achieving excellent results, as has been shown. Here, as in general, the time period duration may be selected to be greater than 10 μs, for example greater than 50 μs, and/or selected in such a way that a predetermined number of time periods results, for example three to thirty time periods. For example, a time period duration of 100 μs has proven to be favorable.

Actual total output durations may differ depending on the type of desired target excitation state or the desired accuracy. For example, the total output duration may be in the range of 300 μs to 7 ms. For example, short-term control sequences include non-selective excitation scenarios, for example with low flip angles, while refocusing control sequences, for example, may have a total output duration of 500 to 700 μs. Inversion processes and layer-selective excitations may last a few milliseconds.

This also makes it possible to estimate the number of optimization parameters required on the basis of the optimization factors as an example. Each complex optimization factor ultimately includes two optimization parameters (imaginary part and real part). For example, if eight transmission channels are used, this results in sixteen optimization parameters for the optimization process per time period. If gradient pulses for three gradient channels are added to this, for example three Cartesian gradient coils, nineteen optimization parameters per time period must be optimized, for five time periods only eighty-five optimization parameters in total, for example.

This is in clear contrast to complete or more extensive optimization, so that for example, to determine the precalculated control sequence, a number of optimization parameters at least ten times, for example at least a hundred times or at least a thousand times, higher than in the optimization process may be used.

It may be useful for the precalculated control sequence to be a universal pulse sequence or a cluster-specific pulse sequence, that is determined as part of a complete optimization for the pulse shapes and/or optimization parameters describing the time sequence for at least one reference examination object. The basis for universal as well as cluster-specific pulse sequences as precalculated control sequences may be field distribution maps and/or comparable information for a cohort of reference examination objects, for example, patients, for which an overall optimum of the high frequency pulses and, if necessary, gradient pulses is determined in a complex optimization process that may take days, weeks or even months. In the case of cluster-specific pulse sequences, the cohort, for example its field distribution maps, is still divided into clusters, it being possible to make an assignment to a respective cluster on the basis of current information about the examination object and/or current field distribution maps, and it thus being possible to select a corresponding cluster-specific pulse sequence as a precalculated control sequence. Specific examples of universal pulse sequences with universal pulses as well as cluster-specific pulse sequences have already been mentioned in the publications discussed in the introduction. An optimization process for determining the at least one precalculated control sequence as a universal pulse sequence or cluster-specific pulse sequence may, for example, be based on a specific pulse shape of the high frequency pulses and/or a specific pulse shape of the gradient pulses, for example a specific transmission k-space trajectory. For example, procedures are known in which so-called CP pulses are assumed for the high frequency pulses.

Specifically, it may be provided that when a plurality of potential precalculated control sequences, each assigned to a cluster, are specified, a current cluster is selected by evaluating at least one variable characteristic of the current detection process and the precalculated control sequence assigned to the current cluster is selected from the potential precalculated control sequences as the cluster-specific control sequence. Here, the variables that characterize the current detection process may, for example, be related to the examination object, for example the patient, and/or the specific examination task, for example, desired contrasts and/or recording areas and/or recording techniques. In embodiments, the characterizing variables may, for example, include a localizer and/or the at least one characterizing variable may be derived from a localizer. It may be particularly advantageous to determine the cluster by evaluating at least part of the field distribution maps, for example the B1 maps and/or by using a trained cluster determination function. A division based on the field distribution maps, for example the B1 maps, has proven to be particularly useful in enabling the provision of excellently preoptimized cluster-specific pulse sequences for each cluster. Corresponding correlations may be detected particularly well via machine learning, so that a trained cluster determination function, for example including a neural network, may be used.

A trained function maps cognitive functions that humans associate with other human brains. By training based on training data (machine learning), the trained function is able to adapt to new circumstances and to detect and extrapolate patterns. Generally speaking, parameters of a trained function may be adjusted by training. For example, supervised learning, semi-supervised learning, unsupervised learning, reinforcement learning and/or active learning may be used. In addition, representation learning (also known as “feature learning”) may also be used. For example, the parameters of the trained function may be adjusted iteratively by a plurality of training steps. A trained function may, for example, include a neural network, a Support Vector Machine (SVM), a decision tree and/or a Bayesian network and/or the trained function may be based on k-means clustering, Q-learning, genetic algorithms and/or assignment rules. For example, a neural network may be a deep neural network, a Convolutional Neural Network (CNN) or a deep CNN. Furthermore, the neural network may be an Adversarial Network, a deep Adversarial Network and/or a Generative Adversarial Network (GAN).

In an embodiment, it may be provided that, in order to carry out the optimization process for each test set of optimization parameters, a test excitation state resulting from the application of the corresponding resulting test control sequence is determined by simulation, is compared with the target excitation state and a deviation measure determined, as a function of which the optimization process is completed and/or a new test set is determined. In such an embodiment, the target function may for example include a term that describes the deviation of the test excitation state from the target excitation state. For example, an MSE loss (“mean square error loss”) may be used as such a measure. Restrictions with regard to the energy input into the examination object (SAR restrictions or SAR minimization) and/or conditions directed towards technical restrictions of the magnetic resonance facility, for example maximum permissible power, currents and the like, may be used as boundary conditions or, if necessary, also further terms of the target function. A target function related to achieving the target excitation state as accurately as possible and/or at least one boundary condition related to the load capacity of the magnetic resonance facility and/or at least one boundary condition related to a SAR load of the examination object may be used in the optimization process. As an initial test set of optimization parameters, i.e., optimization factors, a real-valued one may be set for each optimization factor, as the precalculated control sequence already represents a good starting point. For the current test set of optimization parameters, a current test control sequence is determined by multiplying the pulse shapes in the respective time periods by the optimization factors. Based on this, a simulation, for example a Bloch simulation, may be used to initially determine a magnetization that may be compared with the magnetization of the target excitation state. Based on an evaluation of the target function and any existing boundary conditions, a new test set may be specifically determined, as is generally known, if a cancellation criterion is not fulfilled. For example, a gradient descent method may be used as the optimization algorithm for the optimization process, although other algorithms are also possible.

In a method for acquiring measurement data of an examination object with a magnetic resonance facility, it is provided that a control sequence to be used is provided by a computer-implemented provisioning method and, in the detection process for establishing the target excitation state, the high frequency pulses of the control sequence to be used are output by the high frequency coil arrangement. If the control sequence to be used is also determined including gradient pulses, the gradient pulses are output accordingly via gradient coils of a gradient coil arrangement of the magnetic resonance facility. All embodiments relating to the computer-implemented provisioning method may be transferred analogously to the detection method, so that the advantages already mentioned may also be obtained with this method. For example, the detection method may be used in the clinical field, i.e., for medical imaging, due to its rapid adaptation and provision of the control sequence to be used, in order to obtain high-quality measurement data and thus, for example, also magnetic resonance image data sets.

As already mentioned, it may be useful to record the field distribution maps with the magnetic resonance facility before providing the control sequence to be used. Corresponding, fast magnetic resonance sequences that may be carried out in less than a minute, for example, have already been proposed in the prior art. Alternatively, it would be conceivable, for example, to use measuring probes or the like to measure the field distribution maps.

Embodiments further provide a magnetic resonance facility, having a high frequency coil arrangement and a control facility that is configured to carry out a method. For example, the magnetic resonance facility may also have a gradient coil arrangement for the output of gradient pulses and/or a basic magnetic field strength of at least 7 Tesla, i.e., be configured for ultrahigh field magnetic resonance imaging. The control facility may be configured both to carry out a provisioning method and to carry out a detection method. For example, the control facility may include a provisioning facility that is configured to carry out the computer-implemented provisioning method and may be used by the detection method. All embodiments relating to the method may be transferred analogously to the magnetic resonance facility, so that the advantages already mentioned may also be obtained with this facility.

The control facility includes at least one storage device in which at least one precalculated control sequence may be stored, that may be used as the basis of the provisioning method. The control facility, for example its provisioning facility, may also include a dividing unit for dividing the total output duration into the time periods. Furthermore, an optimization unit may be provided for carrying out the optimization process. For the detection method, the control facility may also have a sequence unit that generally controls the recording operation of the magnetic resonance facility and is therefore configured for example to control the detection process and, if necessary, the recording of the field distribution maps. Further functional units may also be provided for implementing developments of the methods.

A computer program may be loaded directly into a storage a control facility of a magnetic resonance facility and has programming code that, when the computer program is executed, cause the control facility to carry out the steps of a method. The computer program may be stored on an electronically readable data carrier, that thus includes control information stored thereon, that includes at least one computer program and is configured in such a way that, when the data carrier is used in a control facility of a magnetic resonance facility, the latter is configured to carry out a method. When the detection method is implemented as a computer program, the control facility is prompted to correspondingly control further components of the magnetic resonance facility, for example the high frequency coil arrangement and the gradient coil arrangement, in order to detect measurement data and/or field distribution maps.

### BRIEF DESCRIPTION OF THE FIGURES

FIG. 1 depicts a flow chart of a provisioning method according to an embodiment.

FIG. 2 depicts a diagrammatic view of the division of a precalculated control sequence into time periods according to an embodiment.

FIG. 3 a flow chart of a detection method according to an embodiment.

FIG. 4 a schematic diagram of a magnetic resonance facility according to an embodiment.

FIG. 5 the functional structure of a control facility of the magnetic resonance facility according to an embodiment.

### DETAILED DESCRIPTION

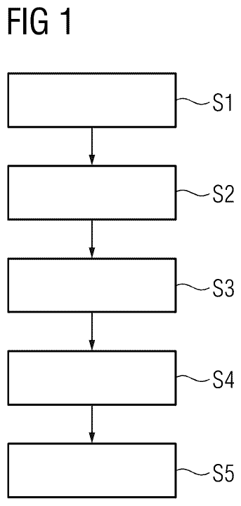

FIG. 1 depicts a flow chart of an embodiment of the provisioning method for providing a control sequence to be used for establishing a target excitation state for a detection process of measurement data of an examination object with a magnetic resonance facility. The magnetic resonance facility has a main magnet that generates a basic magnetic field (B0 field) with a basic field strength of 7 T or more. A high frequency coil arrangement of the magnetic resonance facility has a plurality of high frequency coils that may be controlled via corresponding transmission channels in order to excite spins of the examination object to generate the target excitation state. Furthermore, a gradient coil arrangement is provided that has a plurality of gradient coils, three in the present case, each of which is assigned to one of the Cartesian spatial directions (X, Y, Z) of the magnetic resonance facility. The gradient coils may be controlled via corresponding gradient channels to output gradient pulses.

In the present case, dynamic parallel transmission is to be used to produce the target excitation state, so that the control sequence includes, on the one hand, gradient pulses, for example for converting a transmission k-space trajectory, and on the other hand, high frequency pulses for the transmission channels. These each have highly complex pulse shapes. A plurality of high frequency pulses may also be used per transmission channel (multi-pulse pTx).

Potential precalculated control sequences are stored in a storage a control facility of the magnetic resonance facility. While in other embodiments it is possible to provide only one precalculated control sequence with universal pulses, it is preferred to provide a plurality of potential precalculated control sequences, each of which has been determined for a specific cluster. For this purpose, field distribution maps of a cohort of examination objects, in this case patients, were evaluated in a long-lasting, comprehensive optimization process in order, on the one hand, to assign the field distribution maps to different clusters, and on the other hand, to determine an optimum cluster-specific pulse sequence with cluster-universal pulses for all field distribution maps in each cluster, so that the corresponding cluster-specific pulse sequences may form the potential precalculated control sequences. In this upstream optimization process, that takes place before the examination with the current measurement process, the optimization is carried out using all the optimization parameters that determine the pulse shape and/or the time sequence, for example, for samples no longer than 10 μs, that is the reason for the long duration of the optimization process. The potential precalculated control sequences (for this measurement process) are stored in the storage the control facility, for example with production or an update.

In a step S1, field distribution maps, including a B0 map and B1 maps for each transmission channel, recorded by a fast measurement with the magnetic resonance facility are first provided for the examination object in a manner known in principle. The measurement of the field distribution maps may take 20 to 60 seconds, for example.

In a step S2, a particular, cluster-specific pulse sequence is then determined from the potential precalculated control sequences as the precalculated control sequence for the measurement process. For this purpose, a trained cluster determination function is first used to evaluate the field distribution maps provided in step S1 in order to determine a current cluster. The potential precalculated control sequence assigned to this cluster is then selected as the precalculated control sequence that is to be further optimized.

The precalculated control sequence has a total output duration that is divided, in a step S3, into a plurality of time periods of equal length of a time period duration, for example from 100 to 200 μs. The time period duration may be selected in such a way that the division into time periods of equal length, i.e., the total output duration is divided evenly into a predetermined number of time periods for example. In other exemplary embodiments, the division may be performed in a different manner, the time period duration being greater than the sample length mentioned above.

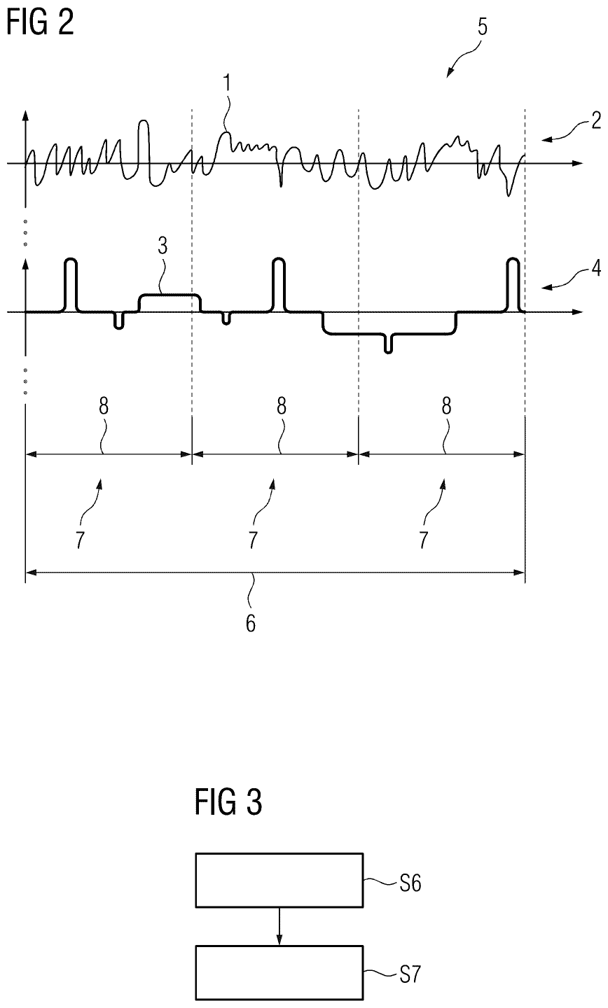

The dividing process is explained in more detail in a purely diagrammatic view by FIG. 2. The pulse shape 1 of a high frequency pulse 2 for one of the transmission channels of the high frequency coil arrangement is shown there purely by way of example and in principle and representatively, wherein the further transmission channels and their high frequency pulses are symbolized only by continuation points. Correspondingly, with regard to the gradient channels, the pulse shape 3 of a gradient pulse 4 is shown only representatively, wherein the further gradient channels in turn are indicated by continuation points. Overall, this results in the precalculated control sequence 5. As already mentioned, it has the total output duration 6 and, in the example shown in FIG. 2, is divided into three time periods 7 of equal length, each of that has a time period duration 8, for example of at least 100 μs. Each channel, i.e., both the transmission channels and the gradient channels, is now assigned an optimization factor for each time period 7, by which the pulse shape 1, 3 is to be multiplied in the respective time period 7 in order to determine further and finally the control sequence to be used in the subsequent optimization. The optimization factors for the pulse shapes 1 of the high frequency pulses 2 are complex, therefore also affect the phase and include two optimization parameters with the real part and the imaginary part. The optimization factors for the pulse shapes 3 of the gradient pulses 4 are real-valued. In other words, the proportions of the pulse shapes 1, 3 in the time periods 7 are scaled according to the optimization factors.

In a step S4, an optimization process then takes place in which optimized optimization factors are determined, from which the control sequence to be used finally may be determined by multiplying the pulse shapes 1, 3 for each time period 7. If, for example, eight transmission channels and three gradient channels are provided, the optimization process for three time periods 7 results in eight times two plus three, multiplied by three, that is to say fifty-seven optimization parameters. This is a significantly lower number, for example by a factor of at least one thousand, than in the optimization process for determining the potential precalculated control sequences 5.

Specifically, in the optimization process of step S4, based on the pulse sequence, that is already cluster-specific, selected as the precalculated control sequence 5, a test set of optimization factors is assumed in which each optimization factor is a real-valued one. Based on this test set, a test control sequence is determined by corresponding multiplication by the optimization factors of the test set, for which a resulting distribution of the magnetization is determined by a Bloch simulation using the field distribution maps. This is compared with the target excitation state in order to determine a deviation measure, for example an MSE measure, that is included in the target function in the present exemplary embodiment and is to be minimized. With regard to the energy input into the examination object, a term of the target function may also be provided, or corresponding boundary conditions are formulated on the basis of SAR requirements. Further boundary conditions relate to the performance or load capacity of the magnetic resonance facility. Depending on the fulfilment of the boundary conditions and the value of the target function, a new test set is either determined or aborted if an abort criterion is met, that may, for example, relate to sufficient fulfilment of the target excitation state and/or a maximum number of optimization steps.

In the present case, the optimization process is carried out according to a gradient descent method, but any other optimization algorithm may also be used.

The result of the optimization process in step S4 are optimized optimization factors and thus a control sequence to be used, that is then provided in step S5 and may be used for the detection process.

This may be done in a detection method, as symbolized by the flow chart in FIG. 3. There, step S6 first describes the recording of the field distribution maps with the magnetic resonance facility. Step S7 describes the entire provisioning process by the provisioning method according to steps S1 to S5, whereupon, in step S8 in the detection process for establishing the target excitation state, the high frequency pulses 2 and the gradient pulses 4 of the control sequence to be used are output by the high frequency coil arrangement and the gradient coil arrangement.

Thus, despite a short adaptation time, wherein the optimization process in step S4 may take a few seconds, for example, high-quality measurement data may be recorded due to excellent fulfilment of the target excitation state. For example, a magnetic resonance image data set may be reconstructed from this data.

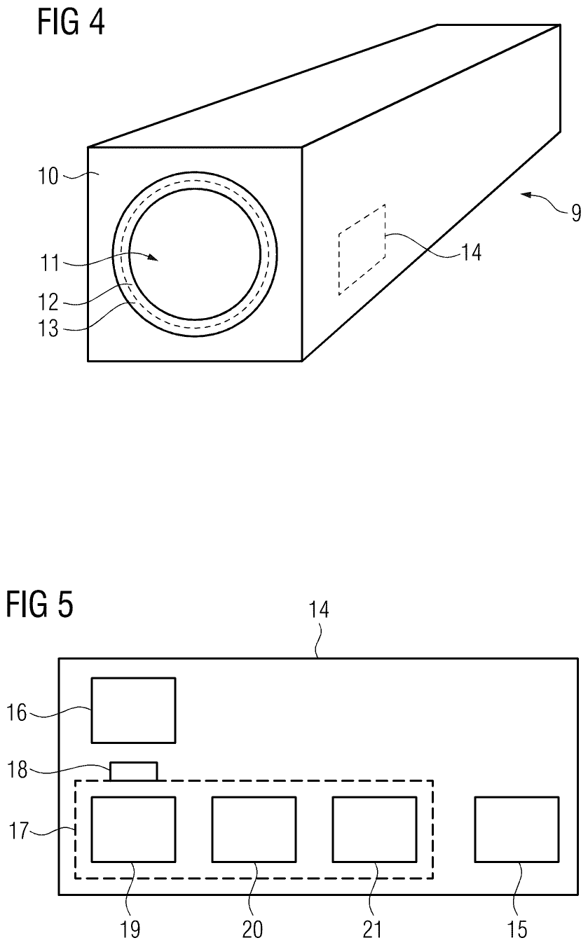

In this regard, FIG. 4 shows a schematic diagram of a magnetic resonance facility 9. As is known in principle, the magnetic resonance facility 9 has a main magnet unit 10 that contains the superconducting main magnet, that in the present case generates a basic magnetic field (B0 field) with a basic magnetic field strength of at least 7 Tesla. The main magnet unit 10 defines a patient holder 11 into which a patient may be moved by a patient couch (not shown in detail here).

A high frequency coil arrangement 12 and a gradient coil arrangement 13 are provided around the patient holder, here only shown in a diagrammatic view. The high frequency coil arrangement 12 or a further high frequency coil arrangement 12 may also be provided as a local coil arrangement and may be arranged close to the patient.

The operation of the magnetic resonance facility 9 is controlled by a control facility 14 that is configured to carry out the methods and the functional structure of which is shown in more detail in FIG. 5.

The control facility 14 thus first includes a storage means 15 in which, for example, the potential precalculated control sequences assigned to the clusters may be stored. Intermediate results and the control sequence to be used may also be stored there.

The recording operation of the magnetic resonance facility 9 is controlled by a sequence unit 16 that, for example, is also configured to control the recording of the field distribution maps according to step S6 and the measurement process according to step S8. A portion of the control facility 14 is formed by a provisioning facility 17 to which the storage means 15 may also belong at least in part and that, generally speaking, is configured to carry out the provisioning method (cf. step S7) with field distribution maps provided, that may be carried out via an interface 18.

For this purpose, the provisioning facility 17 first has a cluster determination unit 19, that is configured to carry out step S2. In a dividing unit 20, the precalculated control sequence 5 may be divided into the time periods 7 according to step S3. An optimization unit 21 is provided for carrying out the optimization process according to step S4. The control sequence to be used may in turn be provided via the interface 18 (step S5).

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for providing a control sequence to be used for establishing a target excitation state for a detection process of measurement data of an examination object with a magnetic resonance facility, wherein the control sequence comprises high frequency pulses to be output via transmission channels of a high frequency coil arrangement, the method comprising:
providing field distribution maps recorded on the examination object, the field distribution maps comprising a B0 map and at least one B1 map;
providing a precalculated control sequence with a total output duration;
dividing the total output duration into a plurality of time periods each of which include a time period duration;
assigning to each time period of the plurality of time periods, a complex optimization factor and a transmission channel by which a pulse shape of the high frequency pulse for the transmission channel is to be multiplied in accordance with the precalculated control sequence within the respective time period;
optimizing one or more complex optimization factors in an optimization process to optimally achieve the target excitation state based on at least the field distribution maps; and
determining the control sequence to be used by time period multiplication of the pulse shapes by the respective optimized optimization factors.

2. The method of claim 1, wherein the control sequence further comprises at least one gradient pulse for at least one gradient channel of a gradient coil arrangement of the magnetic resonance facility, wherein a real-valued optimization factor is assigned to each gradient channel for each time period of the plurality of time periods, optimized in the optimization process, and wherein the pulse shape of each gradient pulse in each time period is multiplied by the respective optimized optimization factor in order to determine the control sequence to be used.

3. The method of claim 1, wherein the time period duration is selected to be the same for all time periods of the plurality of time periods.

4. The method of claim 1, wherein the time period duration is greater than 10 μs and/or is selected in such a way that a predetermined number of time periods comprises between three and thirty time periods.

5. The method of claim 1, wherein the precalculated control sequence is a universal pulse sequence or a cluster-specific pulse sequence that are determined as part of a complete optimization for the pulse shapes and/or optimization parameters describing the time sequence for at least one reference examination object.

6. The method of claim 5, wherein a plurality of potential precalculated control sequences, each assigned to a cluster, are specified and a current cluster is selected by evaluating at least one variable characterizing a current detection process and the precalculated control sequence assigned to the current cluster is selected from the potential precalculated control sequences as the cluster-specific pulse sequence.

7. The method of claim 6, wherein the cluster is determined by evaluating at least part of the field distribution maps and/or using a trained cluster determination function.

8. The method of claim 1, wherein that to carry out the optimization process for each test set of optimization parameters by simulation, a test excitation state resulting from an application of the corresponding resulting test control sequence is determined, is compared with the target excitation state and a deviation measure determined, as a function of which the optimization process is completed and/or a new test set determined.

9. The method of claim 1, wherein in the optimization process, at least one of a target function related to achieving the target excitation state as accurately as possible, at least one boundary condition related to a load capacity of the magnetic resonance facility, or at least one boundary condition related to a SAR load on the examination object is used.

10. The method of claim 1, wherein in the detection process for establishing the target excitation state, the high frequency pulses of the control sequence to be used are output by the high frequency coil arrangement.

11. The method of claim 10, wherein the field distribution maps are recorded with the magnetic resonance facility before the control sequence to be used is provided.

12. A non-transitory computer implemented storage medium that stores machine-readable instructions executable by at least one processor for providing a control sequence to be used for establishing a target excitation state for a detection process of measurement data of an examination object with a magnetic resonance facility, wherein the control sequence comprises high frequency pulses to be output via transmission channels of a high frequency coil arrangement, the machine-readable instructions comprising:
providing field distribution maps recorded on the examination object, the field distribution maps comprising a B0 map and at least one B1 map;
providing a precalculated control sequence with a total output duration;
dividing the total output duration into a plurality of time periods each of which include a time period duration;
assigning to each time period of the plurality of time periods, a complex optimization factor and a transmission channel by which a pulse shape of the high frequency pulse for the transmission channel is to be multiplied in accordance with the precalculated control sequence within the respective time period;
optimizing one or more complex optimization factors in an optimization process to optimally achieve the target excitation state based on at least the field distribution maps; and
determining the control sequence to be used by time period multiplication of the pulse shapes by the respective optimized optimization factors.

13. The non-transitory computer implemented storage medium of claim 12, wherein the control sequence further comprises at least one gradient pulse for at least one gradient channel of a gradient coil arrangement of the magnetic resonance facility, wherein a real-valued optimization factor is assigned to each gradient channel for each time period of the plurality of time periods, optimized in the optimization process, and wherein the pulse shape of each gradient pulse in each time period is multiplied by the respective optimized optimization factor in order to determine the control sequence to be used.

14. The non-transitory computer implemented storage medium of claim 12, wherein the time period duration is selected to be the same for all time periods of the plurality of time periods.

15. The non-transitory computer implemented storage medium of claim 12, wherein the time period duration is greater than 10 μs and/or is selected in such a way that a predetermined number of time periods comprises between three and thirty time periods.

16. The non-transitory computer implemented storage medium of claim 12, wherein the precalculated control sequence is a universal pulse sequence or a cluster-specific pulse sequence that are determined as part of a complete optimization for the pulse shapes and/or optimization parameters describing the time sequence for at least one reference examination object.

17. The non-transitory computer implemented storage medium of claim 16, wherein a plurality of potential precalculated control sequences, each assigned to a cluster, are specified and a current cluster is selected by evaluating at least one variable characterizing a current detection process and the precalculated control sequence assigned to the current cluster is selected from the potential precalculated control sequences as the cluster-specific pulse sequence.

18. The non-transitory computer implemented storage medium of claim 17, wherein the cluster is determined by evaluating at least part of the field distribution maps and/or using a trained cluster determination function.

19. The non-transitory computer implemented storage medium of claim 12, wherein that to carry out the optimization process for each test set of optimization parameters by simulation, a test excitation state resulting from an application of the corresponding resulting test control sequence is determined, is compared with the target excitation state and a deviation measure determined, as a function of which the optimization process is completed and/or a new test set determined.

20. The non-transitory computer implemented storage medium of claim 12, wherein in the optimization process, at least one of a target function related to achieving the target excitation state as accurately as possible, at least one boundary condition related to a load capacity of the magnetic resonance facility, or at least one boundary condition related to a SAR load on the examination object is used.
